(19) United States
(12) Patent Application Publication
(10) Pub. No.: US 2016/0336383 A1
(43) Pub. Date: Nov. 17, 2016

(54) DISPLAY APPARATUS MANUFACTURING METHOD AND DISPLAY APPARATUS

(71) Applicant: JOLED INC., Tokyo (JP)

(72) Inventor: Tomomi HIRAOKA, Tokyo (JP)

(73) Assignee: JOLED INC., Tokyo (JP)

(21) Appl. No.: 15/112,448

(22) PCT Filed: Dec. 22, 2014
(86) PCT No.: PCT/JP2014/006383

§ 371 Date: Jul. 19, 2016

(30) Foreign Application Priority Data
Jan. 23, 2014 (JP) 2014-010764

(51) Int. Cl. H01L 27/32; H01L 51/56

(52) U.S. Cl. CPC H01L 27/3248; H01L 51/56; H01L 2227/323; H01L 2251/568

(57) ABSTRACT

A display apparatus manufacturing method, including: forming a first electrode layer over a substrate; forming a planarization film over the first electrode layer; forming a contact hole in the planarization film; forming a second electrode layer over the planarization film and the contact hole; forming a light-emitting layer over the second electrode layer; forming an upper electrode layer over the light-emitting layer; and irradiating a part of the first electrode layer in a pixel with laser light from a substrate side, so as to connect the part of the first electrode layer to the second electrode layer, the pixel being a pixel having the first electrode and the second electrode which are not in contact with each other in the contact hole, the part being at a position other than in the contact hole.

### TECHNICAL FIELD

The present invention relates to a display apparatus manufacturing method and a display apparatus.

### BACKGROUND ART

Recent years have seen development in techniques related to organic EL display apparatuses each including organic electroluminescent elements (hereinafter also referred to as organic ELS) formed using electro luminescence of organic materials. Conventionally, in an organic EL display apparatus in a manufacturing process, there is a case where foreign matter adheres to the contact part between either an anode or a cathode of the organic EL element and a thin film transistor (TFT) wiring connected to the anode or the cathode, which causes a failure and generates dark spot pixels which are always displayed as dark spots. In this case, a method for repairing (clearing) a failure by irradiating a defective part with laser light is adopted (for example, see Patent Literature 1).

Patent Literature 1 detects conductive foreign matter adhering to the organic EL element, and an organic layer in the area surrounding the foreign matter is irradiated with laser. In this case, the organic layer between the anode and the cathode of the organic EL element with the foreign matter adhering thereto is insulated to form a high resistance area, so as to clear a short-circuit between the anode and the cathode caused by the foreign matter.

### CITATION LIST

### Patent Literature

### [PTL 1]

Japanese Unexamined Patent Application Publication Number 2004-227852

### SUMMARY OF INVENTION

### Technical Problem

The technique according to Patent Literature 1 is a laser light irradiation technique for clearing a short-circuit failure between the anode and the cathode of an organic EL element. Since the laser light irradiation is performed from the display screen side that is the front surface side of a pixel, the area irradiated with the laser light may be damaged and broken. In addition, in the case where a barrier is provided at the display screen side to cover an insulation failure part, it is difficult to clear the failure by laser light irradiation from the display screen side because the insulation failure part is not irradiated with the laser light.

In view of the above problem, the present invention has an object to provide a display apparatus manufacturing method and a display apparatus for repairing dark spot pixels generated due to an insulation failure.

### Solution to Problem

In order to achieve the above object, a display apparatus manufacturing method according to an aspect of the present invention includes: forming a first electrode layer over a substrate; forming a planarization film over the first electrode layer; forming a contact hole in the planarization film; forming a second electrode layer over the planarization film and the contact hole; forming a light-emitting layer over the second electrode layer; forming an upper electrode layer over the light-emitting layer; and irradiating a part of the first electrode layer in a pixel with laser light from a substrate side, so as to connect the part of the first electrode layer to the second electrode layer, the pixel being a pixel having the first electrode and the second electrode which are not in contact with each other in the contact hole, the part being at a position other than in the contact hole.

In order to achieve the above object, a display apparatus manufacturing method according to an aspect of the present invention includes: a first electrode layer on a substrate; a planarization film over the first electrode layer; a contact hole on the planarization film; a second electrode layer over the planarization film and the contact hole; and a light-emitting layer over the second electrode layer, wherein the second electrode layer is not in contact with the first electrode layer in the contact hole, and a part of the first electrode layer is irradiated with laser light from the substrate side so that the first electrode layer is connected to the second electrode layer at the part irradiated with the laser light, the part being at a position other than in the contact hole.

### Advantageous Effects of Invention

According to the present invention, it is possible to provide a display apparatus manufacturing method and a display apparatus for repairing dark spot pixels generated due to an insulation failure.

### BRIEF DESCRIPTION OF DRAWINGS

FIG. 1 is a cross-sectional view of a display apparatus according to an embodiment.

FIG. 2 is a cross-sectional view of a display apparatus according to the embodiment, in a manufacturing process.

FIG. 3 is a cross-sectional view of a display apparatus according to the embodiment, in the manufacturing process.

FIG. 4 is a plan view illustrating laser light irradiation positions according to the embodiment.

FIG. 5 is a flowchart indicating a method for repairing the display apparatus according to the embodiment.

FIG. 6 is an appearance view of a television system in which organic EL elements are provided.

### DESCRIPTION OF EMBODIMENTS

Hereinafter, a display apparatus and a display apparatus manufacturing method according to the present invention have been described based on embodiments. However, the present invention is defined based on the recitation of the claims. Thus, constituent elements which are not recited in the claims among the constituent elements of the embodiments below are described as constituents of preferred embodiments although they are not always required to achieve the object of the present invention. It is to be noted that each of the drawings is a schematic diagram, and is not always precisely illustrated.

### Embodiment

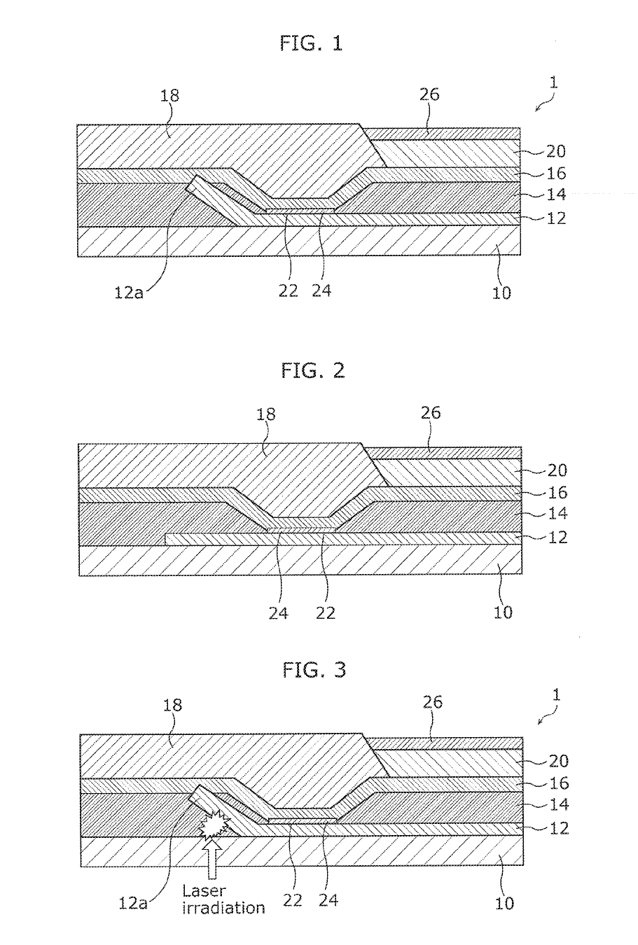

A display apparatus according to an embodiment of the present invention is described. FIG. 1 is a cross-sectional view of a display apparatus according to this embodiment.

As illustrated in FIG. 1, the display apparatus 1 according to this embodiment includes: a substrate 10; a TFT electrode layer 12 formed on the substrate 10; a planarization film 14 formed over the TFT electrode layer 12; an EL electrode layer 16 formed over the planarization film 14; and a light-emitting layer 20 formed over the EL electrode layer 16. The TFT electrode layer 12 is deformed by being irradiated with the laser light from the substrate 10 side so as to be connected to the EL electrode layer 16. Accordingly, it is possible to connect the TFT electrode layer 12 and the EL electrode layer 16 at a part other than in the original contact part 22, and to repair the dark spot pixels generated by the insulation failure.

The substrate 10 is configured with a silicon substrate including a thin film transistor (TFT) for driving.

The TFT electrode layer 12 is formed on the substrate 10. The TFT electrode layer 12 is made of, for example, copper (Cu), and is patterned to have a desired wiring shape. It is to be noted that the TFT electrode layer 12 may be made of any material having an excellent conductivity other than copper. It is to be noted that the TFT electrode layer 12 corresponds to the first electrode layer according to the present disclosure.

The planarization film 14 is formed over the substrate 10 and the TFT electrode layer 12. The planarization film 14 is made of an organic material having an insulation property. In addition, a recess part having the TFT electrode layer 12 as its bottom surface is formed on a part of the planarization film 14, so as to form the contact part 22 for electrically connecting the above TFT electrode layer 12 and the EL electrode layer 16 to be formed in the planarization film 14 later.

The EL electrode layer 16 is formed on the planarization film 14. The EL electrode layer 16 is an anode to which holes are supplied, that is, into which a current flows from an external circuit. The EL electrode layer 16 has, for example, a configuration in which reflector electrodes made of aluminum (Al) or a silver alloy APC etc. are stacked. It is to be noted that the EL electrode layer 16 may have, for example, two-layer configuration made of indium tin oxide (ITO) and the silver alloy APC etc. It is to be noted that the EL electrode layer 16 corresponds to the second electrode layer according to the present disclosure.

Here, a contact failure part 24 is formed in the contact part 22 for electrically connecting the TFT electrode layer 12 and the electrode layer 16. The contact failure part 24 is generated when, for example, foreign matter enters the contact part 22 in a manufacturing process due to material properties etc., or the recess part is insufficiently formed in the planarization film 14. In this way, the TFT electrode layer 12 and the EL electrode layer 16 are not electrically connected, and thus there is an insulation failure.

For this reason, as illustrated in FIG. 1, an end part 12a of the TFT electrode layer 12 is irradiated with laser light so that the end part 12a is bent toward the EL electrode layer 16. In this way, the TFT electrode layer 12 is electrically connected to the EL electrode layer 16 at the end part 12a. It is to be noted that the laser light irradiation is described in detail later.

In addition, the barrier 18 and the light-emitting layer 20 are formed over the EL electrode 16.

The barrier 18 is a barrier for dividing the light-emitting layer 20 into a plurality of light-emission areas, and adjacent pixels are divided by the barrier 18. The barrier 18 is, for example, made of resin having a surface photosensitivity.

The light-emitting layer 20 is a layer which emits light when a voltage is applied between the EL electrode layer 16 and the cathode (not illustrated) formed over the light-emitting layer 20. The light-emitting layer 20 has, for example, a configuration in which the following layers are stacked: α-NPD (Bis [N-(1-naphthyl)-N-phenyl] benzidine) as a lower layer; and Alq₃ (tris-(8-hydroxyquinoline) aluminum) as an upper layer.

It is to be noted that the light-emitting layer 20 may be configured to have, in addition to a layer made of an organic EL, at least one of a hole transporting layer, a hole injecting layer, an electron transporting layer, and an electron injecting layer.

The upper electrode layer 26 that is the cathode is formed over the light-emitting layer 20. Furthermore, a thin film sealing layer, a clear glass, a color filter etc. are formed over the upper electrode layer 26.

For example, the thin film sealing layer is made of silicon nitride (SiN), and has a function for shielding the light-emitting layer 20 and the upper electrode layer 26 from water vapor and oxygen. This is for preventing the light-emitting layer 20 itself or the upper electrode layer 26 from deteriorating (being oxidized) by being exposed to the water vapor and oxygen.

A resin layer for sealing is an acrylic or epoxy resin, and has a function for joining the clear glass and the layer formed integrally from the planarization film 14 formed on the substrate to the thin film sealing layer.

The configuration of EL electrode layer 16, the light-emitting layer 20, and the upper electrode layer 26 is a basic configuration of the organic EL element in the display apparatus 1. With this configuration, when an appropriate voltage is applied to between the EL electrode layer 16 and the upper electrode layer 26, holes are injected from the EL electrode layer 16 side to the light-emitting layer 20 and electrons are injected from the upper electrode layer 26 side to the light-emitting layer 20. The injected holes and electrons are re-coupled in the light-emitting layer 20 to generate energy. With this energy, light-emitting materials in the light-emitting layer 20 are excited and emit light.

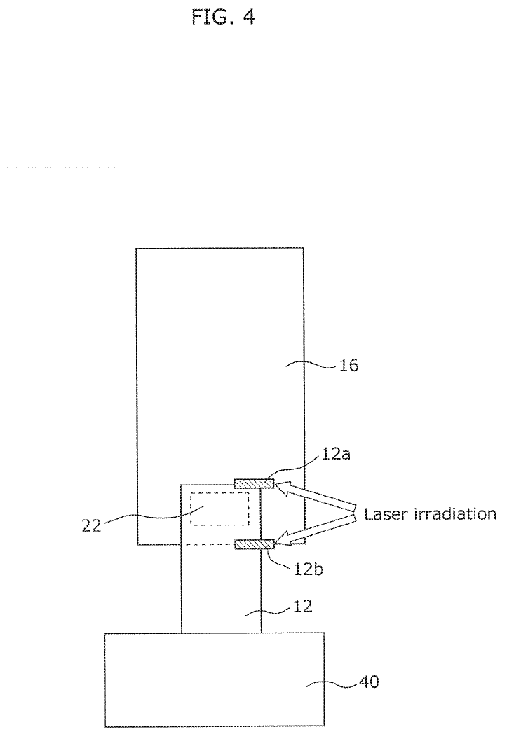

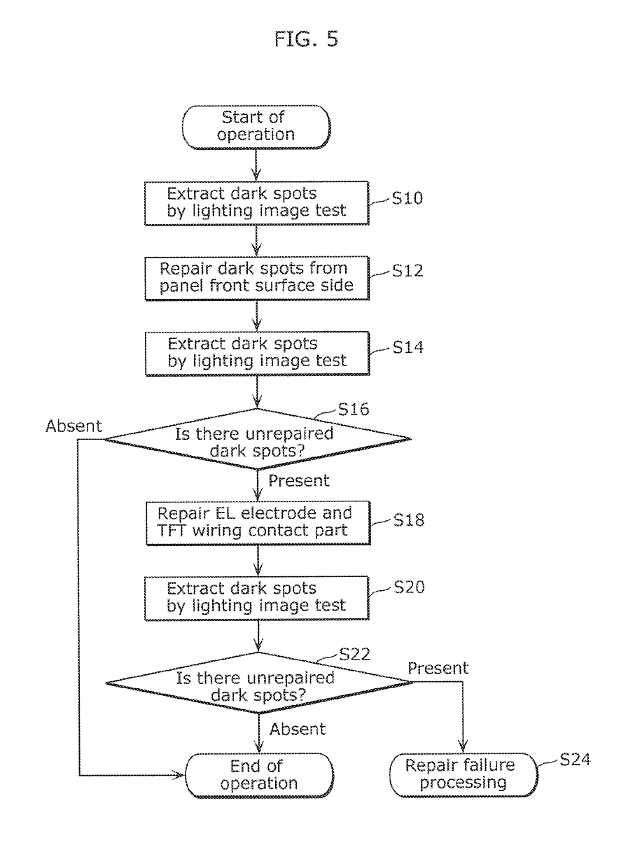

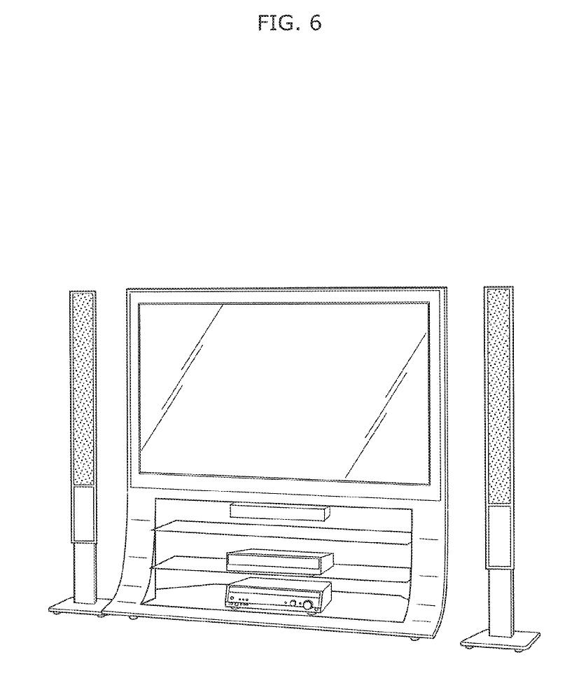

Next, a display apparatus manufacturing method according to this embodiment of the present invention is described. FIGS. 2 and 3 are each a cross-sectional view of a display apparatus according to the embodiment, in the manufacturing process. FIG. 4 is a plan view illustrating laser light irradiation positions according to this embodiment. FIG. 5 is a flowchart indicating a method for repairing the display apparatus according to this embodiment. Although FIG. 4 is a plan view when the display apparatus 1 is seen from the substrate 10 side, it is to be noted that the substrate 10 is not illustrated therein.

The display apparatus 1 according to this embodiment is manufactured as described below.

First, as illustrated in FIG. 2, a TFT electrode layer 12 is formed on a substrate 10 including a TFT. The TFT electrode layer 12 is formed, for example, after a Cu layer is formed on the substrate 10 using a sputtering method, and through a patterning process in which photolithography and wet etching are performed.

Next, a planarization film 14 is formed using an organic material having an insulation property, and then an EL electrode layer 16 is formed on the planarization film 14.

The EL electrode layer 16 is formed, for example, after an Al layer is formed on the planarization film 14 using a sputtering method, and through a patterning process in which photolithography and wet etching are performed.

The light-emitting layer 20 is formed over the planarization film 14 and the EL electrode layer 16 by, for example, depositing α-NPD, Alq₃ using a vacuum evaporation method.

Subsequently, an upper electrode layer 26 is formed. More specifically, the upper electrode layer 26 is formed over the light-emitting layer 20 by depositing ITO using a sputtering method. At this time, the upper electrode layer 26 is in an amorphous state.

Through the above manufacturing process, the organic EL element is configured to have a function as a light-emitting element in the display apparatus 1. It is to be noted that a barrier 18 made of a resin having a surface photosensitivity is formed at a predetermined position between a process in which the EL electrode layer 16 is formed and a process in which the light-emitting layer 20 (a hole injecting layer in the case of a configuration having a hole injecting layer) is formed. In this way, adjacent pixels are divided by the barrier 18.

Furthermore, a thin film sealing layer as a protection layer, a resin layer for sealing, a clear glass etc. are formed on the upper electrode layer 26. For example, the thin film sealing layer is formed by depositing a silicon nitride using a plasma CVD method. Lastly, the clear glass is pressed downward from the upper surface side, the resin layer for sealing is cured by application of heat or energy line, and the clear glass and the thin film sealing layer are bonded.

According to this formation method, the display apparatus 1 as illustrated in FIG. 2 is formed.

It is to be noted that the processes for forming the TFT electrode layer 12, the planarization film 14, the EL electrode layer 16, and the light-emitting layer 20 are not limited to those in this embodiment.

Furthermore, in the case where a short-circuit failure has occurred between the EL electrode layer 16 and the upper electrode layer 26 in the above manufacturing processes, pixels with the shirt-circuit failure are dark spot pixels. In addition, in the case where an insulation failure has occurred between the TFT electrode layer 12 and the EL electrode layer 16, pixels with the insulation failure are dark spot pixels. In this case, the insulation failure at the dark spot pixels are cleared by laser repairing.

Hereinafter, a description is given of a method for repairing the display apparatus performed in the case where dark spot pixels have been generated in the display apparatus manufactured using the above-described method.

As illustrated in FIG. 5, first, dark spot pixels are detected using a lighting image test (Step S10). The dark spot pixels are detected by, for example, inputting a luminance signal voltage corresponding to an intermediate luminance gradation to each of pixels, and detecting each pixel having a luminance lower than the luminance of light emitted by a normal pixel using a luminance measuring device or by eye sight. It is to be noted that the method for detecting dark spot pixels is not limited to the above method, and that dark spot pixels may be detected by, for example, measuring the value of a current flowing between the EL electrode layer 16 and the upper electrode layer 26, and based on the magnitude of the value of the current. In addition, the dark spot pixels may be detected by eye sight, or based on an image captured by a camera.

Next, the dark spot pixels are repaired from the panel surface side (Step S12). More specifically, the dark spot pixels detected in Step S10 in the light-emitting layer 20 or the upper electrode layer 26 are irradiated with laser light from the light-emitting layer 20 side or the barrier 18 side as illustrated in FIG. 2. For example, in the case of dark spot pixels generated due to a short-circuit failure, the upper electrode layer 26 formed to surround the short-circuit part on or over the light-emitting layer 20 of the organic EL element is irradiated with laser light. In this way, either the light-emitting layer 20 or the upper electrode layer 26 of the organic EL element is made to have a high resistance to clear the short-circuit. Thus, the dark spot pixels are turned ON.

It is to be noted that the laser to be used for laser repairing is, for example, an ultra-short pulse laser. The ultra-short pulse laser refers to a laser having a pulse width ranging from a several pico seconds to several femto seconds. Specifically, it is desirable that the ultra-short pulse laser have a pulse width of 100 fs to 20 ps. As an example, in this embodiment, an ultra-short pulse laser having a pulse width of 800 fs (generally also referred to as a femto-second laser) is used. In addition, as an example, the wave length of the laser ranges from 900 to 2500 nm, and output energy is 1 to 50 μJ.

Irradiation of the laser is performed, for example, at the short-circuit part, or an area defined by four sides surrounding foreign matter in the upper electrode layer 26 corresponding to the short-circuit part. In this way, a high resistance area is formed in which at least one of the following is included: ITO which makes a part of the upper electrode layer 26 irradiated with the laser; and constituent elements (an electron transporting layer, an electron injecting layer, etc.) of adjacent function layers and a constituent material (resin etc.) of the thin film sealing layer. In this way, the short-circuit failure between the EL electrode layer 16 and the upper electrode layer 26 is cleared.

It is to be noted that the kind of laser light and irradiation conditions are not limited to those described above, and may be changed as appropriately. In addition, methods for performing laser light irradiation are not limited to the method for performing laser light irradiation around the short-circuit part, and may be the method for performing laser light irradiation on a part of wiring to cut the wiring.

Subsequently, similarly to the case indicated in Step S10, all of pixels are turned ON again, and dark spot pixels are extracted by a lighting image test (Step S14). In this way, it is possible to detect not only dark spot pixels generated due to the short-circuit failure, but also dark spot pixels generated due to the insulation failure.

At this time, in the case where no dark spot pixel is detected (“Absent” in Step S16), the repairing process is ended regarding the repairing of the dark spot pixels as being completed successfully.

In addition, in the case where dark spot pixels are detected again “Present” in Step S16), the dark spot pixels are dark spot pixels caused by the insulation failure. Accordingly, repairing is performed by irradiating the dark spot pixels with laser light from the substrate 10 side (Step S18). More specifically, as illustrated in FIGS. 3 and 4, by irradiating an end part 12a of the TFT electrode layer 12 with laser light from the substrate 10 side, the end part 12a of the TFT electrode layer 12 is bent toward the EL electrode layer 16 side. In this way, the TFT electrode layer 12 and the EL electrode layer 16 are electrically connected at the contact part, it is possible to clear also the dark spot pixels caused by the insulation failure, in addition to the dark spot pixels caused by the short-circuit failure. In addition, by irradiating the end part 12a of the TFT electrode layer 12 with laser light, it is possible to easily deform the end part 12a toward the EL electrode layer 16 side.

It is to be noted that the laser light irradiation position is not limited to the end part 12a, and may be any other part of the TFT electrode layer 12. For example, as illustrated in FIG. 4, laser light irradiation may be performed on a center part 12b of the TFT electrode layer 12.

In addition, the kind of laser light at this time may be, for example, a YAG laser, a short pulse laser, an infrared laser, or the like. In addition, the laser is not limited to a red laser, and may be a green laser. It is desirable that an infrared laser which easily passes through an object be used.

Subsequently, all of pixels are turned ON again, and dark spot pixels are extracted by a lighting image test (Step S20). At this time, in the case where no dark spot pixel is detected (“Absent” in Step S22), the repairing process is ended, with the repairing of the dark spot pixels being regarded as successful.

In addition, in the case where a dark spot pixel is detected again (“Present” in Step S22), the dark spot pixel is regarded as a pixel which cannot be repaired, and a repair failure processing is performed (Step S24). More specifically, the pixel is not used because it is a defective pixel.

As described above, according to the display apparatus and the display apparatus manufacturing method in this embodiment, in the case where dark spot pixels are generated due to an insulation failure, laser light irradiation is performed on the TFT electrode layer 12 so that the TFT electrode layer 12 is bent toward the EL electrode layer 16 side and is connected. Accordingly, it is possible to connect the TFT electrode layer 12 and the EL electrode layer 16 at a part other than in the original contact part 22, and to repair the dark spot pixels generated by the insulation failure.

As described above, a display apparatus manufacturing method according to an aspect of the present invention includes: forming a first electrode layer over a substrate; forming a planarization film over the first electrode layer; forming a contact hole in the planarization film; forming a second electrode layer over the planarization film and the contact hole; forming a light-emitting layer over the second electrode layer; forming an upper electrode layer over the light-emitting layer; and irradiating a part of the first electrode layer in a pixel with laser light from a substrate side, so as to connect the part of the first electrode layer to the second electrode layer, the pixel being a pixel having the first electrode and the second electrode which are not in contact with each other in the contact hole, the part being at a position other than in the contact hole.

With this configuration, the first electrode layer and the second electrode layer can be connected at the part other than in the original contact part, and the dark spot pixels caused by the insulation failure can be repaired.

In addition, the display apparatus manufacturing method may include either the light-emitting layer or the upper electrode layer with laser light from a side opposite the substrate side before irradiating the part of the first electrode layer with the laser light from the substrate side.

With this configuration, the first electrode layer and the second electrode layer are electrically connected at the contact part. Thus, it is possible to repair the dark spot pixels caused by the insulation failure, in addition to the dark spot pixels caused by the short-circuit failure.

In addition, the display apparatus manufacturing method may include forming, over the contact hole, a barrier which covers the contact hole and the second electrode layer.

With this configuration, it is possible to divide the adjacent pixels by the barrier.

In addition, in the irradiating a part of the first electrode layer in a pixel with laser light from the substrate side, so as to connect the first electrode layer to the second electrode layer, the part being at a position other than in the contact hole, an end part of the first electrode layer is irradiated with the laser light.

With this configuration, by irradiating the end part of the first electrode layer with laser light, it is possible to easily deform the end part toward the second electrode layer side.

In addition, the display apparatus manufacturing method may include detecting the pixel having the first electrode layer and the second electrode layer which are not in contact with each other in the contact hole, before the irradiating a part of the first electrode layer in a pixel with laser light from the substrate side, so as to connect the first electrode layer to the second electrode layer, the part being at a position other than in the contact hole.

With this configuration, it is possible to detect not only dark spot pixels caused by the short-circuit failure, but also dark spot pixels caused by the insulation failure.

In addition, a display apparatus according to an aspect of the present invention includes: a first electrode layer on a substrate; a planarization film over the first electrode layer; a contact hole on the planarization film; a second electrode layer over the planarization film and the contact hole; and a light-emitting layer over the second electrode layer, wherein the second electrode layer is not in contact with the first electrode layer in the contact hole, and a part of the first electrode layer is irradiated with laser light from the substrate side so that the first electrode layer is connected to the second electrode layer at the part irradiated with the laser light, the part being at a position other than in the contact hole.

With this configuration, the first electrode layer and the second electrode layer can be connected at the part other than in the original contact part, and the dark spot pixels caused by the insulation failure can be repaired.

In addition, the display apparatus may include a barrier which is over the contact hole and covers the contact hole and the second electrode layer.

With this configuration, it is possible to divide the adjacent pixels by the barrier.

In addition, the first electrode layer may have an end part connected to the second electrode layer.

With this configuration, by irradiating the end part of the first electrode layer with laser light, it is possible to easily deform the end part toward the second electrode layer side.

### Other Embodiments

As described above, the embodiment has been described as an example of a technique disclosed in the present application. However, the technique disclosed herein is not limited to this, and can be applied to other embodiments obtainable through arbitrary modification, replacement, addition, omission, etc. In addition, the embodiment can be modified into new embodiment by arbitrarily combining some of the constituent elements described in the above embodiment.

Hereinafter, other embodiments are collectively described.

In the above embodiment, laser light irradiation is performed, for example, at the end part of the first electrode layer. However, laser light irradiation may be performed at any part other than in the contact part, and thus may be performed at, for example, the center part of the first electrode layer.

In addition, it is to be noted that the light-emitting layer may be configured to have at least one of a hole transporting layer, a hole injecting layer, an electron transporting layer, and an electron injecting layer, in addition to a layer made of an organic EL.

In addition, the kind of a laser light may be, for example, a YAG laser, a short pulse laser, an infrared laser, or the like. In addition, the laser is not limited to a red laser, and may be a green laser. It is desirable that an infrared laser which easily passes through an object be used.

In the above embodiment, an electron device to be used for an organic EL display apparatus etc. has been described. However, the present invention is applicable to liquid crystal electronic devices etc., other electronic devices for which an active matrix substrate is used, display panels, mother boards for mobile terminal panels, etc. In particular, the electron devices configured in this way can be used as flat panel displays, and are applicable to television sets, personal computers, and various kinds of electronic appliances having display panels such as mobile phones.

In addition, for example, the display apparatus according to the present invention is provided to a thin flat TV as illustrated in FIG. 6. With the display apparatus according to the present invention, the thin flat TV capable of displaying high-resolution images reflecting a video signal can be achieved.

The present invention covers other embodiments obtainable by adding various kinds of modifications which may be arrived at any person skilled in the art to any of the above embodiments, and embodiments obtainable by arbitrarily combining the constituent elements and functions in any of the above embodiments within the scope of the present invention.

### INDUSTRIAL APPLICABILITY

The display apparatus according to the present invention can be widely used for thin televisions, personal computers, mobile display apparatuses etc. such as mobile telephones.

### REFERENCE SIGNS LIST

1 Display apparatus
10 Substrate
12 TFT electrode layer (first electrode layer)
12a End part (of first electrode layer)
12b Center part (of first electrode layer)
14 Planarization film
16 EL electrode layer (second electrode layer)
18 Barrier
20 Light-emitting layer
22 Contact part
24 Contact failure part
26 Upper electrode layer

1. A display apparatus manufacturing method, comprising:
forming a first electrode layer over a substrate;
forming a planarization film over the first electrode layer;
forming a contact hole in the planarization film;
forming a second electrode layer over the planarization film and the contact hole;
forming a light-emitting layer over the second electrode layer;
forming an upper electrode layer over the light-emitting layer; and
irradiating a part of the first electrode layer in a pixel with laser light from a substrate side, so as to connect the part of the first electrode layer to the second electrode layer, the pixel being a pixel having the first electrode and the second electrode which are not in contact with each other in the contact hole, the part being at a position other than in the contact hole.

2. The display apparatus manufacturing method according to claim 1, further comprising
irradiating either the light-emitting layer or the upper electrode layer with laser light from a side opposite the substrate side before irradiating the part of the first electrode layer with the laser light from the substrate side.

3. The display apparatus manufacturing method according to claim 1, further comprising
forming, over the contact hole, a barrier which covers the contact hole and the second electrode layer.

4. The display apparatus manufacturing method according to claim 1,
wherein in the irradiating a part of the first electrode layer in a pixel with laser light from the substrate side, so as to connect the first electrode layer to the second electrode layer, the part being at a position other than in the contact hole, an end part of the first electrode layer is irradiated with the laser light.

5. The display apparatus manufacturing method according to claim 1, further comprising
detecting the pixel having the first electrode layer and the second electrode layer which are not in contact with each other in the contact hole, before the irradiating a part of the first electrode layer in a pixel with laser light from the substrate side, so as to connect the first electrode layer to the second electrode layer, the part being at a position other than in the contact hole.

6. A display apparatus, comprising:
a first electrode layer on a substrate;
a planarization film over the first electrode layer;
a contact hole on the planarization film;
a second electrode layer over the planarization film and the contact hole; and
a light-emitting layer over the second electrode layer,
wherein the second electrode layer is not in contact with the first electrode layer in the contact hole, and
a part of the first electrode layer is irradiated with laser light from the substrate side so that the first electrode layer is connected to the second electrode layer at the part irradiated with the laser light, the part being at a position other than in the contact hole.

7. The display apparatus according to claim 6, further comprising
a barrier which is over the contact hole and covers the contact hole and the second electrode layer.

8. The display apparatus according to claim 6,
wherein the first electrode layer has an end part connected to the second electrode layer.
